(19) United States
(12) Patent Application Publication
(10) Pub. No.: US 2025/0218781 A1
(43) Pub. Date: Jul. 3, 2025

(54) SUBSTRATE PROCESSING METHOD AND SUBSTRATE PROCESSING APPARATUS

(71) Applicant: SEMES CO., LTD., Cheonan-si (KR)

(72) Inventors: Tae Shin KIM, Suwon-si (KR); Seryeyohan CHO, Daejeon (KR); Young Dae CHUNG, Incheon (KR); Seung Un OH, Cheonan-si (KR); Hyun YOON, Seoul (KR); Yu Jin CHO, Suwon-si (KR); Ki Hoon CHOI, Cheonan-si (KR)

(73) Assignee: SEMES CO., LTD., Cheonan-si (KR)

(21) Appl. No.: 18/989,573

(22) Filed: Dec. 20, 2024

(30) Foreign Application Priority Data
Dec. 27, 2023 (KR) 10-2023-0192700

(51) Int. Cl. H01L 21/268; G02B 26/02; G02B 27/09

(52) U.S. Cl. CPC H01L 21/268; G02B 26/02; G02B 27/0927; G02B 27/0977

(57) ABSTRACT

The present invention provides a substrate treatment method. The substrate processing method includes: a processing liquid supply step of supplying processing liquid to a substrate; and a heating step of heating a specific area of the substrate by emitting a laser beam, which is generated from a laser source, to the substrate, wherein the heating step may include: a laser modulation step of modulating the laser beam using a light modulation unit; and a laser emission step of emitting the laser beam modulated by the light modulation unit to the specific area.

### CROSS-REFERENCE TO RELATED APPLICATIONS

This application claims priority to and the benefit of Korean Patent Application No. 10-2023-0192700 filed in the Korean Intellectual Property Office on Dec. 27, 2023, the entire contents of which are incorporated herein by reference.

### TECHNICAL FIELD

The present invention relates to a substrate processing method and a substrate processing apparatus and, in more detail, a method and apparatus for processing a substrate by emitting a laser.

### BACKGROUND ART

In order to manufacture a semiconductor device, various processes such as photographing, etching, ashing, ion injection, and thin film deposition are performed on a substrate such as a wafer. Various processing liquids and processing gases are used in the processes. Further, a drying process is performed on a substrate to remove processing liquid, which is used to process the substrate, from the substrate.

Recently, the critical dimension of semiconductor circuits has been miniaturized, so Extreme Ultra-Violet (EUV) light is used as an exposure light source. Further, in accordance with the characteristic of EUV light with a short wavelength, a method of modulating a laser beam L using a light modulation device such as a Digital Micro-mirror Device (hereafter, referred to as a DMD), forming an emission pattern, and emitting the emission pattern to a mask or a wafer is used.

Meanwhile, it is possible to heat a specific area of a substrate by emitting light to the upper surface of a substrate having a liquid film formed by chemical liquid. The entire pattern on a substrate is etched by chemical liquid and a specific area to which light is emitted can be more etched because it is heated. The degree of etching depends on the amount of heat transmitted by light per unit and a DMD can form emission patterns having various shapes, so it is possible to control etching for a substrate M in various ways.

When a specific area of a substrate M is set and light having flat top distribution is modulated through a DMD and emitted to the specific area to uniformly heat the specific area, there is a problem that uniform temperature distribution is not formed in the specific area due to blurring, etc. in the edge region of light, and accordingly, the substrate M is not etched into a desired shape.

### SUMMARY OF THE INVENTION

An objective of the present invention is to provide a substrate processing method and a substrate processing apparatus that can effectively process substrates.

Further, an objective of the present invention is to provide a substrate processing method and a substrate processing apparatus that can effectively adjust the critical dimension of a pattern formed on a substrate.

Further, an objective of the present invention is to provide a substrate processing method and a substrate processing apparatus that can adjust the shape or distribution of a laser that is emitted to a substrate into a desired shape or distribution.

Further, an objective of the present invention is to provide a substrate processing method and a substrate processing apparatus that can emit a laser such that temperature distribution in a specific area of a substrate that needs to be heated becomes uniform.

The objectives of the present invention are not limited thereto and other objectives not stated herein may be clearly understood by those skilled in the art from the following description.

The present invention provides a substrate treatment method. The substrate processing method includes: a processing liquid supply step of supplying processing liquid to a substrate; and a heating step of heating a specific area of the substrate by emitting a laser beam, which is generated from a laser source, to the substrate, wherein the heating step may include: a laser modulation step of modulating the laser beam using a light modulation unit; and a laser emission step of emitting the laser beam modulated by the light modulation unit to the specific area.

In an embodiment, the light modulation unit may be a Digital Micro-mirror Device (DMD) unit, and the DMD unit may include: micromirrors provided to be rotatable; and a board substrate on which the micromirrors are installed.

In an embodiment, the laser modulation step may selectively switch an ON state in which the laser beam is reflected to the substrate and an OFF state in which the laser beam is dumped by adjusting a direction in which the micromirrors each reflect the laser beam.

In an embodiment, in the laser modulation step, the micromirrors each may adjust time for which the laser beam is emitted to the substrate by controlling time for maintaining the ON state and the OFF state.

In an embodiment, in the laser modulation step, the micromirrors each may adjust a shape or distribution density of the laser beam in the specific area by maintaining the ON state or the OFF state for entire time for heating the specific area.

In an embodiment, in the laser modulation step, the laser beam may be modulated by individually or simultaneously changing a shape or distribution of the laser beam using the DMD unit.

In an embodiment, in the laser modulation step, when the distribution of the laser beam is changed, the laser beam may be changed such that intensity of the laser beam to be emitted to an edge region of the specific area is higher than intensity of the laser beam to be emitted to a center region of the specific area.

In an embodiment, in the laser modulation step, when the shape of the laser beam is changed, the laser beam may be changed such that side portions of the laser beam are recessed.

In an embodiment, in the laser modulation step, when heat transfer coefficients of the substrate in a first direction in the specific area and in a second direction different from the first direction are different from each other, the laser beam may be changed to have different shapes or distribution in the first direction and the second direction to uniformly heat the specific area.

In an embodiment, the heating step may further include a laser type conversion step of converting a type of the laser beam before the laser modulation step, and a Gaussian-type laser generated from the laser source may be converted into a flat top-type laser beam in the laser type conversion step.

In an embodiment, the specific area may be a rectangle.

Further, the present invention provides a substrate processing apparatus. The substrate processing apparatus includes: a supporting unit supporting a substrate; a liquid supply unit supplying liquid to the substrate supported on the supporting unit; a laser emission module emitting a laser beam to a specific area on the substrate supported on the supporting unit; a moving unit changing a position of the laser emission module; and a control unit controlling the laser emission module and the moving unit, wherein the laser emission module includes: a laser source generating a laser beam; and a Digital Micro-mirror Device (DMD) unit that is a light modulation unit modulating the laser beam generated from the laser source, the DMD unit includes: micromirrors provided to be rotatable; and a board substrate on which the micromirrors are installed, and the control unit performs control to individually or simultaneously change a shape or distribution of the laser beam by adjusting a direction in which the micromirrors each reflect the laser beam.

In an embodiment, the control unit may perform control such that the micromirrors each selectively switch an ON state in which the laser beam is reflected to the substrate and an OFF state in which the laser beam is dumped.

In an embodiment, when the distribution of the laser beam is changed, the control unit may change the laser beam such that intensity of the laser beam to be emitted to an edge region of the specific area is higher than intensity of the laser beam to be emitted to a center region of the specific area.

In an embodiment, when the shape of the laser beam is changed, the control unit may change the laser beam such that side portions of the laser beam are recessed.

In an embodiment, the specific area may be a rectangle.

Further, the present invention provides a substrate processing method. The substrate processing method includes: a processing liquid supply step of supplying processing liquid to a substrate; and a heating step of heating a specific area of the substrate by emitting a laser beam, which is generated from a laser source, to the substrate with the processing liquid remaining, wherein the specific area is a rectangle, the heating step includes: a laser type conversion step of converting a type of the a laser beam into a flat top-type laser beam; a laser modulation step of modulating the laser beam using a Digital Micro-mirror Device (DMD) unit comprising micromirrors provided to be rotatable; and a laser emission step of emitting the laser beam modulated by the DMD unit to the specific area, and the laser modulation step selectively switches an ON state in which the laser beam is reflected to the substrate and an OFF state in which the laser beam is dumped by adjusting a direction in which the micromirrors each reflect the laser beam, and modulates the laser beam by individually or simultaneously changing a shape or distribution of the laser beam.

In an embodiment, in the laser modulation step, when the distribution of the laser beam is changed, the laser beam may be changed such that intensity of the laser beam to be emitted to an edge region of the specific area is higher than intensity of the laser beam to be emitted to a center region of the specific area.

In an embodiment, in the laser modulation step, when the shape of the laser beam is changed, the laser beam may be changed such that side portions of the laser beam are recessed.

In an embodiment, in the laser modulation step, when heat transfer coefficients of the substrate in a first direction in the specific area and in a second direction different from the first direction are different from each other, the laser beam may be changed to have different shapes or distribution in the first direction and the second direction to uniformly heat the specific area.

According to an embodiment of the present invention, it is possible to effectively process a substrate.

Further, according to an embodiment of the present invention, it is possible to effectively etch a substrate.

Further, according to an embodiment of the present invention, it is possible to adjust the shape or distribution of a laser that is emitted to a substrate into a desired shape or distribution.

Further, according to an embodiment of the present invention, it is possible to simultaneously emit a laser such that temperature distribution in a substrate that needs to be heated becomes uniform.

Effects of the present invention are not limited to those described above and effects not stated above will be clearly understood to those skilled in the art from the specification and the accompanying drawings.

### BRIEF DESCRIPTION OF THE DRAWINGS

FIG. 1 is a plan view schematically showing a substrate processing apparatus according to an embodiment of the present invention.

FIG. 2 is a view schematically showing the appearance of a substrate that is processed in the liquid processing chamber of FIG. 1.

FIG. 3 is a view schematically showing an embodiment of the liquid processing chamber of FIG. 1.

FIG. 4 is a view schematically showing the configuration of the laser emission module of FIG. 3.

FIG. 5 is a graph showing distribution of a laser beam that is output from a laser source.

FIG. 6 is a graph showing distribution of a laser beam that has passed through a beam shaper.

FIG. 7 is a view schematically showing the appearance of a light modulation device.

FIG. 8 is a view showing that a laser beam is output from a light modulation device.

FIG. 9 is a view showing that a laser beam output from the light modulation device is removed at an optical dumber.

FIG. 10 is a view for explaining the principle that a laser beam is removed at an optical dumper.

FIG. 11 is a view for explaining an emission pattern of a laser beam that is output from a light modulation unit.

FIG. 12 is a flowchart showing a substrate processing method according to an embodiment of the present invention.

FIG. 13 is a cross-sectional view showing the appearance of a substrate processing apparatus that performs a processing liquid supply step according to an embodiment.

FIG. 14 is a cross-sectional view showing the appearance of the substrate processing apparatus that performs a heating step according to an embodiment.

FIG. 15 shows a laser beam having a uniform intensity distribution in a specific area in the same shape as the specific area.

FIG. 16 briefly shows temperature distribution of a specific area of a substrate when the laser beam of FIG. 15 is emitted to the specific area.

FIG. 17 shows an embodiment when a light modulation unit changes the distribution of a laser beam.

FIG. 18 is a graph schematically showing the profile of a laser beam that is emitted to a substrate in accordance with the embodiment of FIG. 17.

FIG. 19 shows an embodiment when a light modulation unit changes the shape of a laser beam.

FIG. 20 shows an embodiment when the distribution and the shape of a laser beam are both changed.

FIG. 21 and FIG. 22 show the shape and the distribution of a laser that is emitted to a specific area of a substrate that shows different heat transfer coefficients in a first direction and a second direction.

FIG. 23 briefly shows the state of a micromirror when the micromirror changes the shape of a laser through operation position control.

FIG. 24 is a cross-sectional view showing the appearance of a substrate processing apparatus that performs a rinse solution supply step according to an embodiment.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

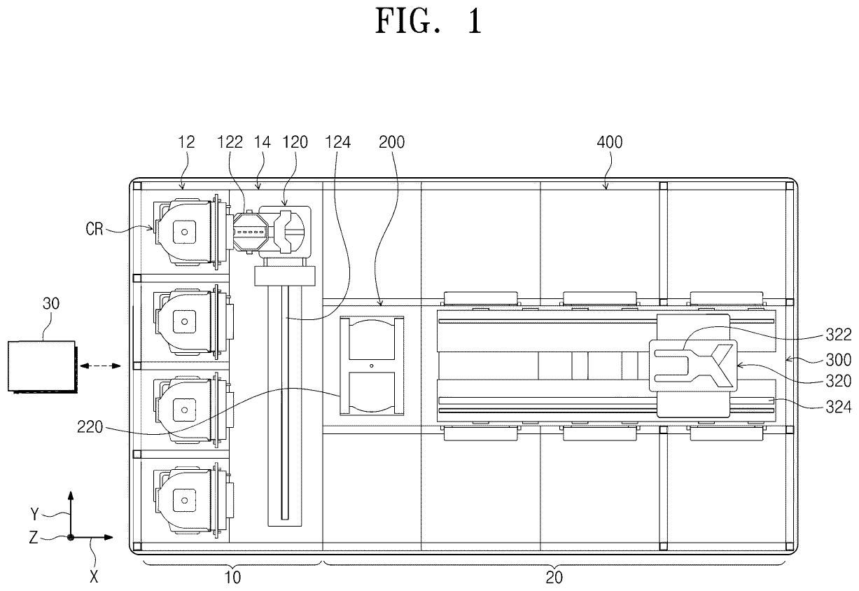

Hereafter, embodiments of the present invention are described with reference to FIG. 1 to FIG. 20.

FIG. 1 is a plan view schematically showing a substrate processing apparatus according to an embodiment of the present invention.

Referring to FIG. 1, a substrate processing apparatus includes an index module 10, a processing module 20, and a control unit 30. When seen from above, the index module 10 and the processing module 20 are disposed in one direction. Hereafter, the direction in which the index module 10 and the processing module 20 are arranged is referred to as a first direction X, a direction perpendicular to the first direction X when seen from above is referred to as a second direction Y, and a direction perpendicular to both of the first direction X and the second direction Y is referred to as a third direction Z.

The index module 10 transfers substrates M to the processing module 20 from containers CR accommodating the substrates M and puts the substrates M processed at the processing module 20 into the containers CR. The longitudinal direction of the index module 10 is provided in the second direction Y. The index module 10 has a load port 12 and an index frame 14. The load port 12 is positioned at the opposite side to the processing module 20 with the index frame 14 therebetween. The containers CR accommodating substrates M are placed in the load port 12. A plurality of load ports 12 may be provided and the plurality of load ports 12 may be disposed in the second direction Y.

The container CR may be a container for sealing such as a Front Open Unified Pod (FOUP). The container CR may be placed in the load port 12 by a worker or a conveying device (not shown) such as an overhead transfer, an overhead conveyor, or an automatic guided vehicle.

An index robot 120 is provided at the index frame 14. A guide rail 124 of which the longitudinal direction is provided in the second direction Y is provided in the index frame 14 and the index robot 120 may be provided to be movable on the guide rail 124. The index robot 120 includes a hand 122 on which substrates M are placed and the hand 122 may be provided to be able to move forward and backward, rotate about the third direction Z, and move in the third direction Z. A plurality of hands 122 may be provided to be spaced apart from each other in the up-down direction and the hands 122 can move forward and backward independently from each other.

The control unit 30 can control the components of the substrate processing apparatus. The control unit 30 may include: a process controller that is a microprocessor (computer) that performs control of the operation of the substrate processing apparatus; a user interface that is a keyboard through which an operator performs command input operation, etc. to manage the substrate processing apparatus, a display that visualizes and displays the operation situation of the substrate processing apparatus, etc.; and a memory that stores a control program for performing processing, which is performed in the substrate processing apparatus, under control of the process controller, a program for performing processing on each component in accordance with various data and processing conditions, that is, a processing recipe. Further, the user interface and the memory may be connected to the process controller. The processing recipe may be stored in a memory medium of the memory unit and the memory medium may be a hard disk and may be a portable disc such as a CD-ROM and a DVD, and a semiconductor memory such as a flash memory.

The control unit 30 can control the substrate processing apparatus to be able to perform the substrate processing method to be described below. For example, the control unit 30 can control the components provided in a liquid processing chamber 400 to be able to perform the substrate processing method to be described below.

The processing module 20 includes a buffer unit 200, a transfer chamber 300, and a liquid processing chamber 400. The buffer unit 200 provides a space in which substrates M that are loaded into the processing module 20 and substrates M that are unloaded from the processing module 20 temporarily stay. The liquid processing chamber 400 performs a liquid processing process of liquid processing on substrates M by supplying liquid onto the substrates M. The transfer chamber 300 transfers substrates M between the buffer unit 200 and the liquid processing chamber 400.

The longitudinal direction of the transfer chamber 300 may be provided in the first direction X. The buffer unit 200 may be disposed between the index module 10 and the transfer chamber 300. The liquid processing chamber 400 may be disposed on a side of the transfer chamber 300. The liquid processing chamber 400 and the transfer chamber 300 may be disposed in the second direction Y. The buffer unit 200 may be positioned at an end of the transfer chamber 300.

According to an example, the liquid processing chambers 400 may be disposed at both sides of the transfer chamber 300. The liquid processing chambers 400 may be provided in an array of A X B (A and B are each a natural number of 1 or more) in the first direction X and the third direction Z, respectively, at a side of the transfer chamber 300.

The transfer chamber 300 has a transfer robot 320. A guide rail 324 of which the longitudinal direction is provided in the first direction X is provided in the transfer chamber 300 and the transfer robot 320 may be provided to be movable on the guide rail 324. The transfer robot 320 includes a hand 322 on which substrates M are placed and the hand 322 may be provided to be able to move forward and backward, rotate about the third direction Z, and move in the third direction Z. A plurality of hands 322 may be provided to be spaced apart from each other in the up-down direction and the hands 322 can move forward and backward independently from each other.

The buffer unit 200 has a plurality of buffers 220 on which substrates M are placed. The buffers 220 may be disposed to be spaced apart from each other in the third direction Z. The buffer unit 200 is open on the front face and the rear face. The front face is a surface that faces the index module 10 and the rear face is a surface that faces the transfer chamber 300. The index robot 120 can approach the buffer unit 200 through a front face and the transfer robot 320 can approach the buffer unit 200 through a rear face.

Hereafter, substrates M that are processed in the liquid processing chamber 400 are described in detail.

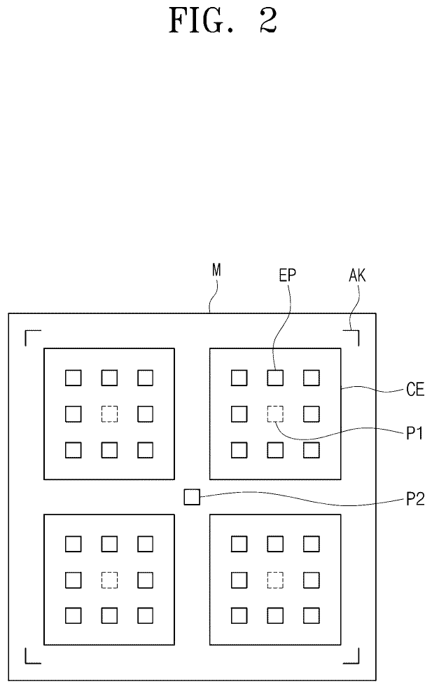

FIG. 2 is a view schematically showing the appearance of a substrate that is processed in the liquid processing chamber of FIG. 1.

Referring to FIG. 2, a processing target that is processed in the liquid processing chamber 400 may be any one substrate of a wafer, a glass, and a photomask. Hereafter, it is exemplarily described that the substrate M that is processed in the liquid processing chamber 400 is a photomask that is a ‘frame’ that is used in an exposure process.

The substrate M may have a rectangular shape. The substrate M may be a mask that is a ‘frame’ that is used in an exposure process. At least one or more reference marks AK may be formed on the substrate M. For example, a plurality of reference marks AK may be formed at the corner regions of the substrate M, respectively. The reference marks AK may be marks that are called align keys and used to align the substrate M. Further, the reference marks AK may be marks that are used to derive position information of the substrate M. For example, a vision sensor (not shown) such as a camera may be provided in the liquid processing chamber 400, the vision sensor obtains an image by photographing the reference marks AK, and the control unit 30 can detect the position and direction of the substrate M by analyzing the images including the reference marks AK. Further, the reference marks AK may be marks that are used to find out position of the substrate M when the substrate M is transferred.

A cell CE may be formed on the substrate M. At least one or more cells CE, for example, a plurality of cells CE may be formed. A plurality of patterns may be formed in each cell CE. The patterns formed in each cell CE may be defined as one pattern group. The patterns formed in the cell CE may include an exposure patterns EP and a first pattern P1. The exposure patterns EP can be used to form an actual pattern on the substrate M. Further, the first pattern P1 may be a pattern that represents exposure patterns EP formed in one cell CE. Further, when a plurality of cells CE is provided, a plurality of first patterns P1 may be provided. Further, a plurality of first patterns P1 may be formed in one cell CE. The first pattern P1 may have a shape that is a combination of portions of exposure patterns EP. The first pattern P1 may be referred to as a monitoring pattern. Further, the first pattern P1 may be referred to as a critical dimension monitoring macro.

When a worker inspects the first pattern P1 through a scanning electron microscope (SEM), it is possible to presume whether the shapes of the exposure patterns EP formed in one cell CE are good or poor. Further, the first pattern P1 may be a pattern for inspection. Further, the first pattern P1 may be any one pattern of exposure patterns EP actually participating in an exposure process. Further, the first pattern P1 may be a pattern for inspection and simultaneously an exposure pattern actually participating in exposure.

A second pattern P2 may be a pattern that represents exposure patterns EP formed on the entire substrate M. For example, the second pattern P2 may have a shape that is a combination of portions of first patterns P1.

When a worker inspects the second pattern P2 through a scanning electron microscope (SEM), it is possible to presume whether the shapes of the exposure patterns EP formed in one substrate are good or poor. Further, the second pattern P2 may be a pattern for inspection. Further, the second pattern P2 may be a pattern that actually does not participate in an exposure process. The second pattern P2 may be referred to as an anchor pattern.

Hereafter, a substrate processing apparatus that is provided at the liquid processing chamber 400 is described in detail. The liquid processing chamber 400 performs a predetermined process on substrates M. In more detail, the process that is performed in the liquid processing chamber 400 may be Fine Critical Dimension Correction (FCC) in a process of manufacturing a mask for an exposure process. In substrates M that are loaded into the liquid processing chamber 400, it may be required to adjust the critical dimension of at least one or more of a first pattern P1, a second pattern P2, and exposure patterns EP. That is, in the process chamber 400, it is possible to etch a specific pattern (e.g., a second pattern P2) of a plurality of patterns formed on a substrate M. Further, the substrate M that is processed in the process chamber 400 may be a post-processed substrate M.

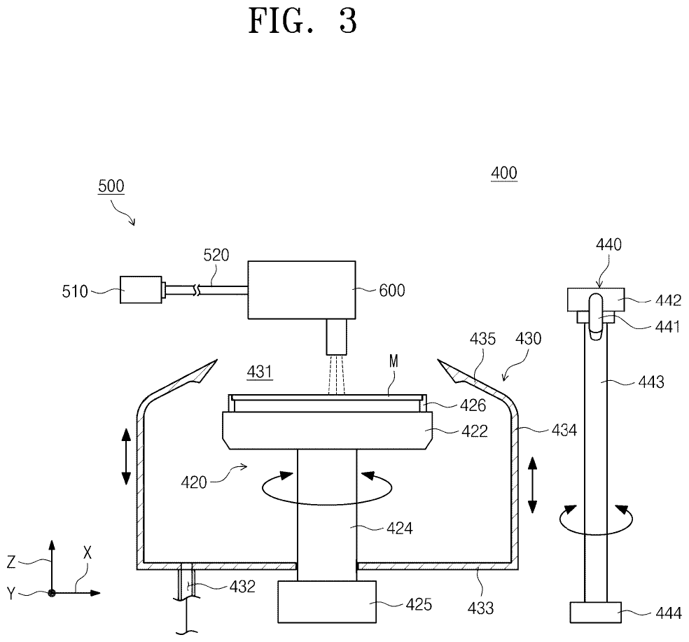

FIG. 3 is a view schematically showing an embodiment of the liquid processing chamber of FIG. 1. Referring to FIG. 3, the liquid processing chamber 400 includes a supporting unit 420, a bowl 430, a chemical liquid supply unit 440, and a laser emission assembly 500.

The supporting unit 420 can support a substrate M in a processing space 431 defined by the bowl 430 to be described below. The supporting unit 420 can support a substrate M. The supporting unit 420 can rotate the substrate M.

The supporting unit 420 may include a chuck 422, a supporting shaft 424, an actuating member 425, and a supporting pin 426. The supporting pin 426 may be installed on the chuck 422. The chuck 422 may have a plate shape having a predetermined thickness. The supporting shaft 424 may be coupled to the lower portion of the chuck 422. The supporting shaft 424 may be a hollow shaft. Further, the supporting shaft 424 can be rotated by the actuating member 425. The actuating member 425 may be a hollow motor. When the actuating member 425 rotates the supporting shaft 424, the chuck 422 coupled to the supporting shaft 424 can be rotated. The substrate M placed on the supporting pin 426 installed on the chuck 233 can also be rotated by rotation of the chuck 422.

The supporting pin 426 can support a substrate M. The supporting pin 426 may have a substantially circular shape when seen from above. Further, when seen from above, the supporting pin 426 may have a shape recessed downward at the portions corresponding to the corner regions of a substrate M. That is, the supporting pin 426 may include a first surface supporting the lower portions of the corner regions of a substrate M and a second surface facing the sides of the corner regions of the substrate M to be able to restrict lateral movement of the substrate M when the substrate M is rotated. At least one or more supporting pins 426 may be provided. A plurality of supporting pins 426 may be provided. The supporting pins 426 may be provided in the number corresponding to the number of the corner regions of a substrate M having a rectangular shape. The supporting pins 426 can space the bottom surface of a substrate M and the top surface of the chuck 422 by supporting the substrate M.

The bowl 430 may have a cylindrical shape with open top. The bowl 430 can define the processing space 431. A substrate M can be liquid-processed and heated in the processing space 431. The bowl 430 can prevent processing liquid that is supplied to a substrate M from being scattered and transmitted to the chemical liquid supply unit 440 and the laser emission assembly 500.

The bowl 430 may include a bottom portion 433, a vertical potion 434, and an inclined portion 435. An opening in which the supporting shaft 424 can be inserted may be formed at the bottom portion 433 when seen from above. The vertical portion 434 may extend in the third direction Z from the bottom portion 433. The inclined portion 435 may extend at an angle upward from the vertical portion 434. For example, the inclined portion 435 may extend at an angle toward a substrate M supported on the supporting unit 420. A discharge hole 432 that can discharge processing liquid, which is supplied from the chemical liquid supply unit 440, to the outside may be formed through the bottom portion 433.

Further, the bowl 430 is coupled to an elevation member (not shown), so the position thereof can be changed in the third direction Z. The elevation member may be an actuating device that moves up and down the bowl 430. The elevation member can move up the bowl 430 while liquid processing and/or heating processing is performed on a substrate M, and can move down the bowl 430 when a substrate M is loaded into the liquid processing chamber 400 or a substrate M is unloaded from the processing chamber 400.

The chemical liquid supply unit 440 can supply chemical liquid for performing liquid processing on a substrate M. The liquid supply unit 440 can supply chemical liquid to a substrate M supported on the supporting unit 420. The chemical liquid may be an etching solution or a rinse solution. The etching solution may be a chemical. The etching solution can etch the pattern formed on a substrate M. The etching solution may be referred to as an etchant. The rinse solution can wash a substrate M. The rinse solution may be provided as well-known chemical liquid.

The chemical liquid supply unit 440 may include a nozzle 441, a fixing body 442, a rotary shaft 443, and a rotary member 444.

The nozzle 411 can supply processing liquid to a substrate M supported on the supporting unit 420. A first end of the nozzle 441 may be connected to the fixing body 442 and a second end may extend toward a substrate M from the fixing body 442. The nozzle 411 may extend in the first direction X from the fixed body 442. Further, the second end of the nozzle 411 may bend at an angle and extend toward a substrate M supported on the supporting unit 420.

If necessary, a plurality of nozzles 441 may be provided. Any one of the nozzles 441 may be a nozzle that discharges the etching solution described above and another one of the nozzles 441 may be a nozzle that discharges the rinse solution described above.

The body 442 can fix and support the nozzle 441. The body 442 may be connected with the rotary shaft 443 that is rotated around the third direction Z by the rotary member 444. When the rotary member 444 rotates the rotary shaft 443, the body 442 can be rotated around the third direction Z. Accordingly, the outlet of the nozzle 441 can be moved between a liquid supply position that is a position where processing liquid is supplied to a substrate M and a standby position that is a position where processing liquid is not supplied to a substrate M.

The laser emission assembly 500 can emit a laser to a substrate M. The laser emission assembly 500 can adjust the critical dimension of the pattern formed on a substrate M by emitting a laser to the substrate M with the pattern formed on the top surface, by a chemical liquid (e.g., an etching solution) that is supplied by the chemical liquid supply unit 440. The temperature of the region of a substrate M to which the laser emitted by the laser emission assembly 500 is emitted can be increased. Accordingly, the region emitted with a laser can be relatively more etched and the region not emitted with a laser can be relatively less etched. In this way, it is possible to adjust the critical dimension of the pattern formed on a substrate M.

The laser emission assembly 500 includes a laser source 410, a laser transmission member 520, and a laser emission module 600.

The laser source 510 can generate light L. The laser source 510 can generate light having straightness. The light generated by the laser source 510 can be emitted to a substrate M and can heat the substrate M. The light L may be a laser beam, a fiber laser, a laser diode, or the like. Hereafter, it is exemplarily described that light is a laser beam L. The power of a laser beam L may be adjusted in accordance with process requirement conditions. The laser source 510 may have power of a range within 20 W per unit area (cm²). When the laser source 510 has power of a range within 20 W per unit area (cm²), a light modulation device 642 to be described below can be appropriately driven without being damaged.

The laser transmission member 520 transmits the laser beam L generated by the laser source 510 to the laser emission module 600. According to an example, the laser transmission member 520 may be an optical fiber.

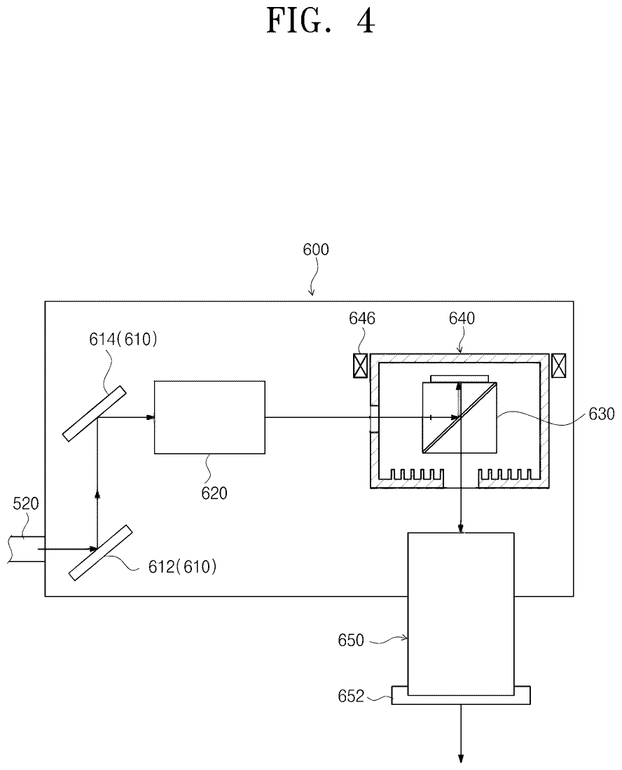

FIG. 4 is a view schematically showing the configuration of the laser emission module of FIG. 3.

The laser emission module 600 includes a mirror 610, a beam shaper 620, a prism optical device 630, a light modulation unit 640, and an imaging unit 650.

The mirror 610 reflects and transmits laser beam L traveling into the laser emission module 600 through the laser transmission member 520 to the beam shaper 620. The mirror 610 may include a plurality of mirrors to appropriately reflect the path of the laser beam L. For example, the mirror 610 may include a first mirror 612 and a second mirror 614.

The beam shaper 620 can change the type of the light that is output from the laser source 510.

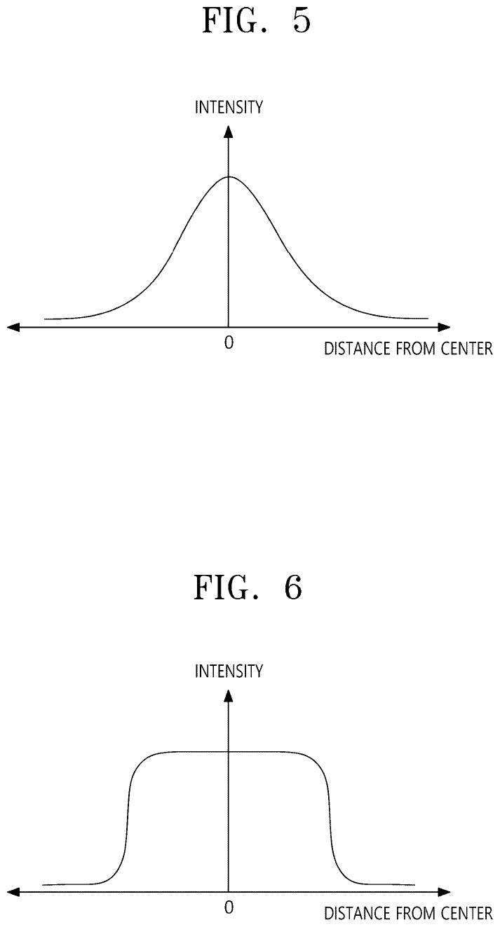

FIG. 5 is a graph showing distribution of laser beam that is output from a laser source and FIG. 6 is a graph showing distribution of laser beam that has passed through a beam shaper.

Referring to FIG. 4 to FIG. 6, the laser beam L that is output from the laser source 510, as shown in FIG. 6, may have a Gaussian type in which the strength distribution has Gaussian distribution. In more detail, the intensity of the laser beam L that is output from the laser source 510 may be high at the center of the laser beam L and the intensity (strength) thereof may gradually decrease as it goes away from the center of the laser beam L (see FIG. 5). Accordingly, when the laser beam L that is output from the laser source 510 is emitted to a substrate M, the region close to the center of the laser beam L can be more heated and the region close to the edge of the laser beam L can be less heated. Accordingly, in the laser emission module 600 according to an embodiment of the present invention, the beam shaper 620 may be disposed on the traveling path of the laser beam L output from the laser source 510. The beam shaper 620 can change Gaussian-type laser beam L that is output from the laser source 510 into flat top-type laser beam L. The laser beam L that is output from the laser source 510 can be converted into a flat top type having flat top distribution, in which the intensity (luminance) distribution is relatively uniform, through the beam shaper 620 (see FIG. 6).

Referring to FIG. 4 again, the laser beam L that has passed through the beam shaper 620 can be transmitted to the prism optical device 630.

The prism optical device 630 can reflect the laser beam L that has passed through the beam shaper 620 back to the light modulation unit 640. The laser beam L transmitted to the light modulation unit 640 can be modulated at the light modulation unit 620 and then output. The laser beam L modulated and output from the light modulation unit 640 can be transmitted to the imaging unit 650 through the prism optical device 630.

The light modulation unit 640 can modulate the transmitted laser beam L. The light modulation unit 640 may include a light modulation device 642, an optical dumper 644, and a cooling device 646.

The light modulation device 642 can modulate the shape and the distribution of the laser beam L that is generated by the laser source 510. In this case, modulation of the shape and the distribution of the laser beam L may be forming shape and distribution of a laser beam L corresponding to the emission pattern of a laser beam L to be emitted to a substrate M.

The light modulation device 642 may be a Digital Micro-mirror Device (DMD).

That is, the light modulation unit 640 may be a DMD unit including a Digital Micro-mirror Device (DMD).

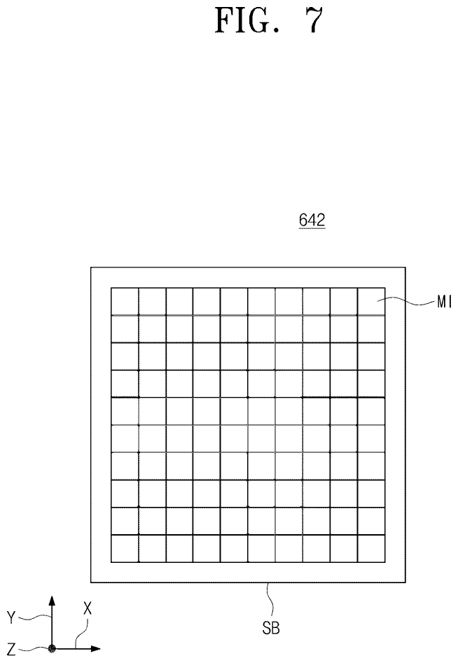

FIG. 7 is a view schematically showing the appearance of a light modulation device. The light modulation device 642 may include a board substrate SB and a plurality of mirrors MI. Electrodes corresponding to the plurality of micromirrors MI, respectively, may be installed on the board substrate SB. The control unit 30 can transmit a digital signal of “0” or “1” to the electrodes installed on the board substrate SB. The micromirrors MI may be configured to be rotatable. The micromirrors MI can be configured to be rotatable around a direction that is parallel with a plane passing through the first direction X, the second direction Y, or the first direction X and the second direction Y. A micromirror MI corresponding to an electrode receiving a digital signal of “0” can become an OFF state and a micromirror MI corresponding to an electrode receiving a digital signal of “1” can become an ON state. A micromirror MI in the ON state can emit a laser beam L to a substrate and a laser beam L reflected by a micromirror MI in the OFF state may not be emitted to a substrate M.

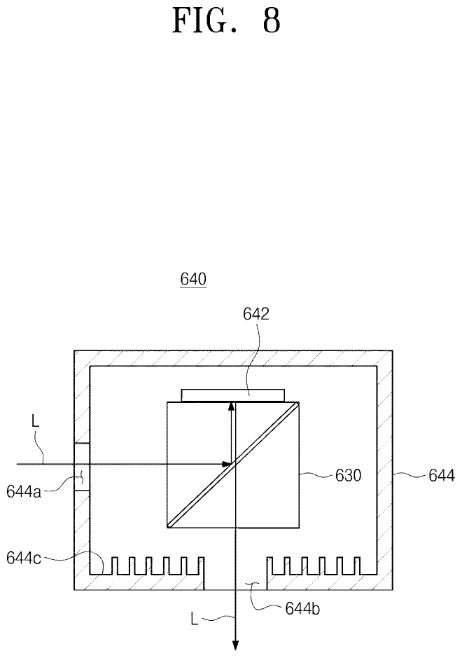

FIG. 8 is a view showing that a laser beam is output from a light modulation device. In FIG. 8, for the convenience of description, the traveling path of light that is reflected by any one micromirror MI of micromirrors MI is shown. Referring to FIG. 4, FIG. 7, and FIG. 8, a micromirror MI in the ON state can transmit light to a substrate M through the imaging unit 650 to be described below.

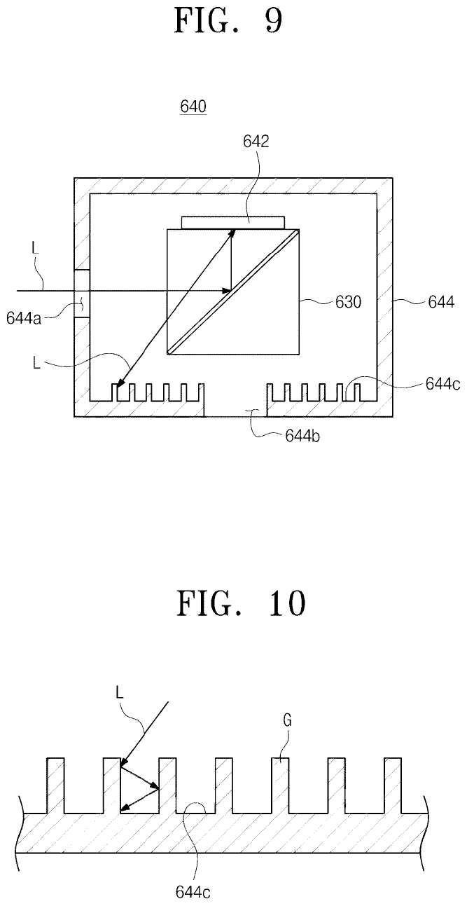

FIG. 9 is a view showing that a laser beam output from the light modulation device is removed at an optical dumber. In FIG. 9, for the convenience of description, the traveling path of a laser beam L that is reflected by any one micromirror MI of micromirrors MI is shown. Referring to FIG. 4, FIG. 7, and FIG. 9, a micromirror MI in the OFF state may not transmit a laser beam L to a substrate M by reflecting the laser beam L. In detail, micromirrors MI are configured to be rotatable, as described above. A micromirror MI in the OFF state may make a laser beam not be transmitted to a substrate M by changing the traveling path of laser beam L received from the laser source 510 by rotating. The laser beam L that is discharged from the micromirror MI in the OFF state may become extinct by being emitted to the inner surface of the optical dumber 644 without passing through a second hole 644b of the optical dumper 644. That is, a micromirror in the OFF state can dump a laser beam L.

FIG. 10 is a view for explaining the principle that a laser beam is removed at an optical dumper. Referring to FIG. 4 and FIG. 10, the optical dumber 644 may have a box shape. The optical dumber 644 may be made of a material that can remove a laser beam by absorbing it such as synthetic resin. The prism optical device 630 may be disposed in the internal space of the optical dumber 644. The light modulation device 642 may be disposed in the internal space of the optical dumber 644 or may be installed outside the optical dumber 644.

A first hole 644a and a second hole 644b may be formed at the optical dumber 644. The first hole 644a may be formed on a side of the optical dumber 644. The first hole 644a may be a hole through which a laser beam L generated by the laser source 510 and converted through the beam shaper 620 passes. The second hole 644b may be a hole through which a laser beam L modulated by the light modulation device 641 passes. The second hole 644b may be formed on the lower portion of the optical dumber 644.

Grooves G may be formed on the inner surface 644c of the optical dumber 644. The grooves G formed on the inner surface 644c of the optical dumber 644 may be configured to be able to absorb the light reflected by a micromirror MI in the OFF state. In detail, when a laser beam L is transmitted to the grooves G, the laser beam L can be removed by being reflected several times at the grooves G. The laser beam L can be removed while being reflected several time at the grooves G and losing energy to the optical dumber 644. In FIG. 4 and FIG. 10, it is exemplarily shown that grooves G are formed only on the lower portion of the optical dumber 644, but the present invention is not limited thereto and grooves G may be formed on the entire inner surface 644c of the optical dumber 644.

Referring to FIG. 4 again, since the optical dumber 644 removes a laser beam L, the temperature of the optical dumber 644 can be increased. Accordingly, the light modulation unit 640 according to an embodiment of the present invention may include the cooling device 646 that cools the optical dumber 644. The cooling device 646 may be a fan that generates airflow for cooling the optical dumber 644.

The imaging unit 650 can emit a laser beam L that has been modulated and output from the light modulation unit 640 and has passed through the prism optical device 630 to a substrate M by adjusting the laser beam L to correspond to an area to which the laser beam L is emitted. The imaging unit 650 includes a plurality of lenses that can adjust the size of a laser beam L, and can adjust the profile of a laser that is emitted to a substrate M by increasing or decreasing the diameter of a laser beam L.

The imaging unit 650 may include a component that removes a noise pattern from refractive patterns output from the light modulation unit 640. For example, the imaging unit 650 may include a spatial filter.

The imaging unit 650 includes an emission lens 652. A laser beam L that has been modulated and output from the light modulation unit 640 and has passed through the prism optical device 630 is adjusted by the imaging unit 650 and emitted to a substrate M through the emission lens 652.

As described above, the laser beam L modulated by the light modulation unit 640 and adjusted by the imaging unit 650 is emitted to a substrate M. The laser emission module 600 can heat a specific area SA of a substrate M by emitting a laser beam L to the specific area SA of the substrate M. The specific area SA may be a rectangular region.

The laser emission assembly 500 may further include a moving unit (not shown) that can move between a standby position and a position where a laser beam L is emitted to a substrate M supported on the supporting unit 420.

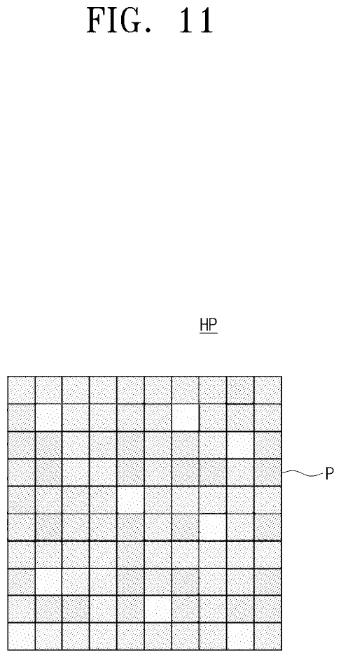

FIG. 11 is a view for explaining an emission pattern of a laser beam that is output from a light modulation unit. Referring to FIG. 4, FIG. 7, and FIG. 11, as described above, micromirrors MI can be changed between the ON state and the OFF state. The micromirrors MI each can selectively switch an ON state in which they reflect a laser beam L to a substrate M and an OFF state in which a laser beam L is dumped by adjusting the reflective direction of a laser beam L. The micromirrors MI each can adjust time for which a laser beam L is emitted to a substrate M by adjusting time for which they maintain the ON state and the OFF state.

The state changing of each micromirror MI between the ON state and the OFF state can be made within a very short time. By On-OFF state changing of each micromirror MI, the light modulation unit 640 can form very various emission patterns HP.

For example, in FIG. 11, the amount of heat that is transmitted to a substrate M per unit time by a laser beam L reflected by each micromirror MI for unit time (e.g., 1 second) is shown. The emission pattern HP may be composed of a plurality of patterns P corresponding to micromirrors MI, respectively. In order to increase the amount of heat that is transmitted to a substrate M per unit time from each micromirror MI, it is possible to maintain the ON state of the micromirrors MI for a long time and maintain the OFF state for a short time. In order to decrease the amount of heat that is transmitted to a substrate per unit time from each micromirror MI, it is possible to maintain the ON state of the micromirrors MI for a short time and maintain the OFF state for a long time.

The laser emission module 600 including the light modulation unit 640 can convert a laser beam L into a rectangular uniform laser beam L by adjusting the On/OFF state of each micromirror MI and through the imaging unit 650.

Further, the laser emission module 600 including the light modulation unit 640 can convert a laser beam L converted into a flat top type through the beam shaper 620 into a rectangular uniform laser beam L by adjusting the On/OFF state of each micromirror MI and through the imaging unit 650.

Further, the light modulation unit 640 can change individually or simultaneously the shape or the distribution of a laser beam L by adjusting the On/OFF states of the micromirrors MI described above.

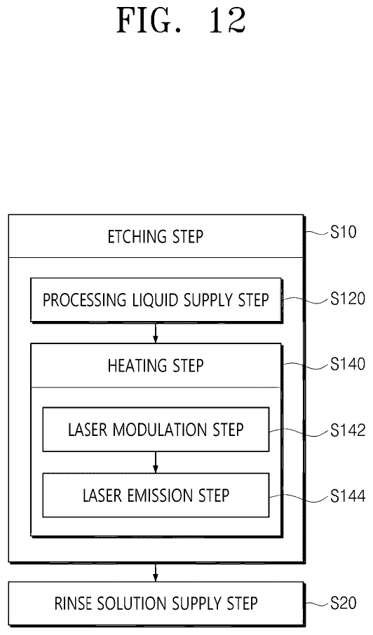

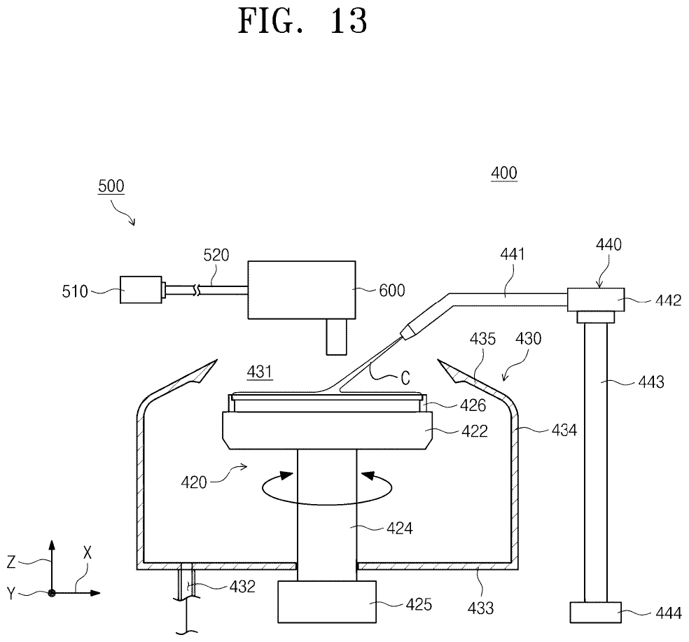

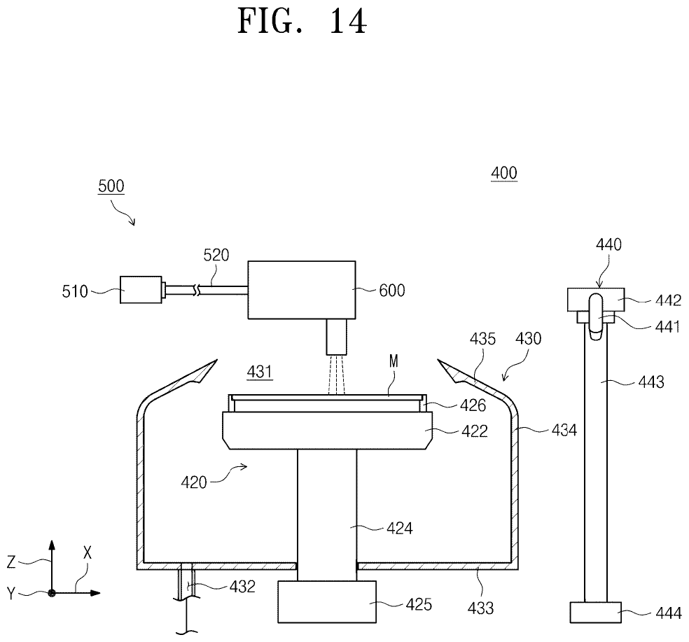

FIG. 12 is a flowchart showing a substrate processing method according to an embodiment of the present invention. FIG. 13 is a cross-sectional view showing the appearance of a substrate processing apparatus that performs a processing liquid supply step according to an embodiment. FIG. 14 is a cross-sectional view showing the appearance of the substrate processing apparatus that performs a heating step according to an embodiment. FIG. 13 is a view schematically showing the intensity of a laser emitted to a substrate in the heating step according to an embodiment.

Hereafter, a substrate processing method according to an embodiment of the present invention is described with reference to FIG. 12 to FIG. 24. The substrate processing method to be described hereafter is performed by the substrate processing apparatus described above, so the reference numerals cited in FIG. 2 to FIG. 11 are equally cited hereafter. Further, the substrate processing method according to an embodiment may be performed by controlling the components of the substrate processing apparatus by means of the control unit 30.

The substrate processing method according to an embodiment may include an etching step S10 and a rinse solution supply step S20. The etching step S10 and the rinse solution supply step S20 may be performed sequentially in time series.

The process of processing a substrate M in the etching step S10 may be Fine Critical Dimension Correction (FCC) described above. The etching step S10 etches a specific area of a substrate M. In more detail, the etching step S10 etches the region in which a second pattern P2 of a first pattern P1 and the second pattern P2 is formed on a substrate M.

The etching step S10 may include a processing liquid supply step S120 and a heating step S140. The processing liquid supply step S120 and the heating step S140 may be sequentially performed.

As shown in FIG. 13, the chemical liquid supply step S120 supplies chemical liquid C onto the substrate M. According to an embodiment, in the chemical liquid supply step S30, it is possible to supply chemical liquid C to the substrate M. When chemical liquid C is supplied to a substrate M that has stopped rotating, chemical liquid C may be supplied by an amount that can form a liquid film or a puddle.

For example, the amount of chemical liquid C that is supplied to a substrate can be supplied such that it covers the entire top surface of the substrate M and does not flow off the substrate M, or if it does flow off, the amount is no significant. If necessary, it is possible to form a liquid film or a puddle on a substrate by supplying chemical liquid C to the substrate M that is rotating or by supplying chemical liquid C to the entire top surface of the substrate M while changing the position of the nozzle 452.

As shown in FIG. 14, the heating step S140 heats the substrate M. In more detail, the laser emission assembly 500 emits a laser beam L to a specific area (e.g., the region in which the second pattern P2 is formed) of the substrate M with a liquid film. The laser that is emitted to the substrate M can be emitted to the specific area SA on the substrate M.

According to an embodiment, the heating step S140 may include a laser modulation step S142 and a laser emission step S144.

In the laser modulation step S142, the light modulation unit 640 can change individually or simultaneously the shape or the distribution of a laser by adjusting the On/OFF states of the micromirrors MI described above. It is possible to modulate a laser beam L such that the temperature profile of the laser that is emitted to the substrate M becomes uniform by changing the shape and the distribution of the laser through the light modulation unit 640.

The laser emission step S144 can heat a specific area of the substrate M by emitting light to the top surface of the substrate M with the liquid film formed by the chemical liquid C. The entire pattern on the substrate M is etched by chemical liquid and the specific area emitted with a laser beam L can be more etched because it is heated. The degree of etching depends on the amount of heat transmitted by a laser beam per unit time and the light modulation unit 640 of the present invention can form emission patterns having various shapes, so it is possible to control etching for a substrate M in various ways. In the light emission step S144, the supporting unit 420 can support the substrate M without rotating it.

The laser emission module 600 can emit a laser to the specific area SA and then emit a laser to another region that needs to be heated on the substrate M through the moving unit (not shown).

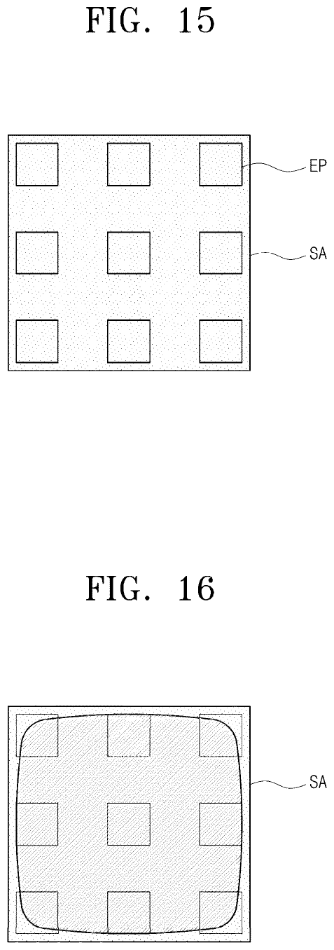

FIG. 15 to FIG. 22 show the shape and the distribution of a laser that is modulated and output by the light modulation unit and then emitted to a specific area of a substrate M.

FIG. 15 shows a laser beam having uniform intensity distribution in a specific area in the same shape as the specific area and FIG. 16 briefly shows temperature distribution of a specific area of a substrate when a laser beam is emitted to the specific area.

As shown in FIG. 15, when a flat top-type laser having a size the same as the size of a specific area SA of a substrate M is emitted to the specific area SA, temperature distribution around the edge of the specific area SA may not be uniform in comparison to the center region of the specific area SA, as can be seen from the temperature distribution shown in FIG. 16, due to blurring of the laser beam that is emitted around the edge of the specific area SA, etc. Accordingly, the exposure patterns EP around the edge of the specific area SA may not be uniformly etched.

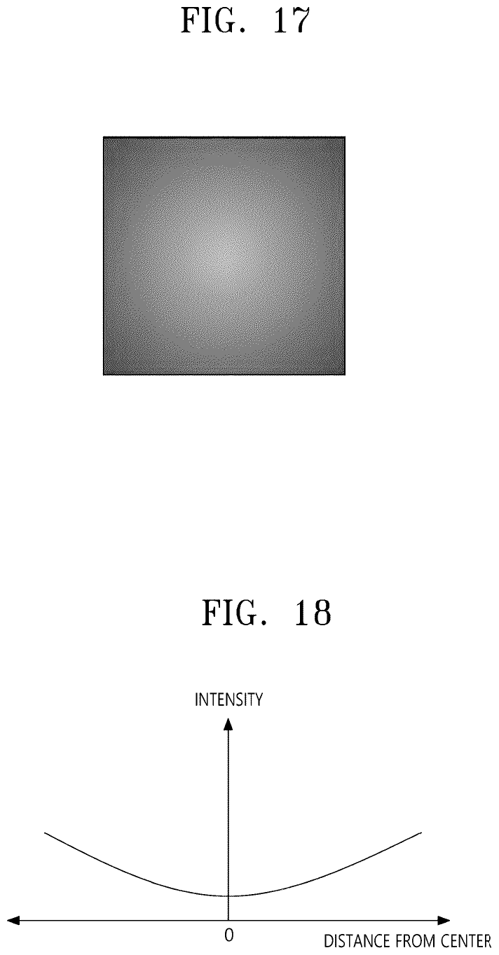

FIG. 17 shows an embodiment when a light modulation unit changes the distribution of a laser beam and FIG. 18 is a graph schematically showing the profile of a laser beam that is emitted to a substrate in accordance with the embodiment of FIG. 17. Referring to FIG. 17 and FIG. 18, the light modulation unit 640 can change the distribution of a laser by adjusting the On/OFF state of the micromirrors MI described above. For example, the light modulation unit 640, as shown in FIG. 17, can change a flat top-type rectangular laser beam into a rectangular laser beam having reinforced edge intensity distribution. The rectangular laser beam having reinforced edge intensity distribution is a laser beam changed such that the intensity of the laser beam when the laser beam is emitted to an edge region of a specific area SA is higher than the intensity of the laser beam when the laser beam is emitted to the center region of the specific area SA. Accordingly, as shown in FIG. 18, the profile of a laser beam L that is emitted to a specific area SA may have so-called dog ear distribution in which the shape is the same before and after changing, but the intensity is low and increases toward the edge.

FIG. 19 shows an embodiment when a light modulation unit changes the shape of a laser beam. As described above, the light modulation unit 640 can change the shape of a laser by adjusting the reflective angle and the On/OFF state of the micromirrors MI described above. For example, the light modulation unit 640 can change the shape of a flat top-type rectangular laser beam into a so-called pin-cushion type in which the side portions of a laser beam are recessed.

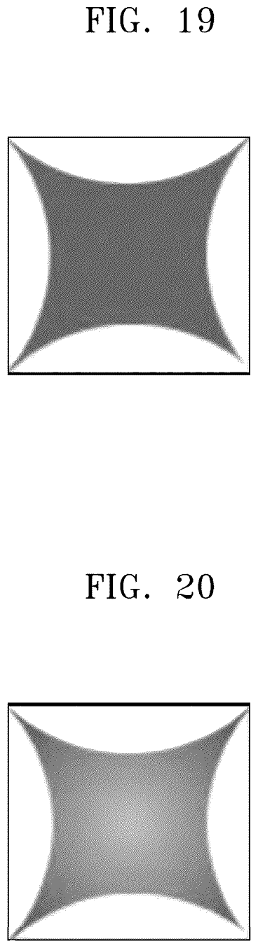

FIG. 20 shows an embodiment when the distribution and the shape of a laser beam are both changed. The light modulation unit 640 can change both of the shape and the distribution of a laser by adjusting the On/OFF state of the micromirrors MI described above. For example, as shown in FIG. 20, the light modulation unit 640 can change the shape of a laser beam into a pin-cushion type and change the distribution of the laser beam into dog ear distribution.

In the embodiment described above, which is an embodiment of changing the shape of a substrate, a so-called pin-cushion type in which the side portions of a laser beam are recessed was described. However, the present invention is not limited thereto and the light modulation unit 640 can freely change the shape of a laser beam L by adjusting micromirrors MI.

When emitting a laser into a specific area SA of a substrate M that needs to be heated, it is possible to consider the heat transfer coefficient of the substrate M. When the entire specific area SA to which a laser beam L is emitted on a substrate M has the same heat transfer coefficient, it is possible to make the temperature profile of the substrate M uniform by emitting a laser beam L having a shape that is symmetric with respect to the center of the specific area SA.

However, when the heat transfer coefficient of a substrate M shows different characteristics in a first direction and a second direction, it is required to form a laser beam L such that the laser beam L has different curvatures and distribution in the first direction and the second direction. For example, when the heat transfer coefficient of a substrate M in the first direction is higher than the heat transfer coefficient in the second direction, heat transfer of the substrate M in the first direction is faster than heat transfer in the second direction. In this case, the light emission module 640 changes the shape of the laser beam in the first direction to be recessed more than the shape of the laser beam in the second direction, so it is possible to change the laser beam to have different curvatures in the first direction and the second direction, whereby it is possible to ensure uniformity of he temperature profile in the first direction and the second direction. Alternatively, it is possible to adjust the intensity of a laser beam at the edge in the second direction to be higher than the intensity of the laser beam at the edge in the first direction by changing the distribution of the laser beam.

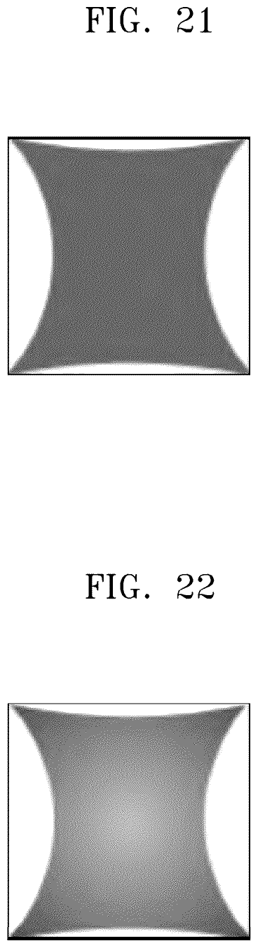

FIG. 21 and FIG. 22 show the shape and the distribution of a laser that is emitted to a specific area of a substrate that shows different heat transfer coefficients in a first direction and a second direction.

Referring to FIG. 21 and FIG. 22, a laser beam having a pin-cushion shape is emitted, as shown in FIG. 21.

When a substrate M has different heat transfer coefficients in a first direction and a second direction, for example, the first direction is referred to as a direction that is parallel with the X-axis (hereafter, referred to as an “X-direction”) and the second direction is referred to as a direction that is parallel with the Y-axis (hereafter, referred to as an “Y-direction”), and when the heat transfer coefficient of a substrate M in the X-direction is higher than the heat transfer coefficient in the Y-direction, heat transfer of the substrate M in the X-direction is faster than heat transfer in the Y-direction. In this case, the light modulation unit 640, as shown in FIG. 21, changes the shape of a laser beam in the X-direction to be recessed more than the shape of the laser beam in the Y-direction, whereby it is possible to ensure uniformity of the temperature profile in the X-direction and the Y-direction. Further, as shown in FIG. 22, in addition to change a laser beam into the shape of FIG. 21, it is possible to change the distribution of a laser beam. That is, it is possible to adjust the intensity of a laser beam at the edge in the Y-direction (up-down edge) to be higher than the intensity of the laser beam at the edge in the X-direction (left-right edge).

According to the embodiments described above, the light modulation unit 640 can individually or simultaneously change the shape or the distribution of a laser beam that is emitted to a specific area SA of a substrate M such that a uniform temperature profile is derived in the specific area SA. That is, it is possible to adjust the shape or the distribution of a laser beam that is emitted to a substrate into a desired shape or distribution and it is possible to emit a laser such that the temperature distribution in a specific area SA of a substrate M that needs to be heated becomes uniform. Accordingly, it is possible to control the temperature distribution in a specific area SA and it is possible to effectively edge a substrate in accordance with desired shapes.

In the embodiment described above, it was described that the emission time of a laser beam to the substrate is adjusted by controlling the time for maintaining the ON state and the OFF state through the micromirrors MI of the light modulation unit 640 when changing the shape or the distribution of the laser beam. However, it is possible to change the shape or the distribution of a laser beam using also the distribution of the ON state and the OFF state of each of the micromirrors MI other than the operation time control of the micromirrors MI. That is, it is possible to change the shape or the distribution of a laser beam through operation position control of the micromirrors MI.

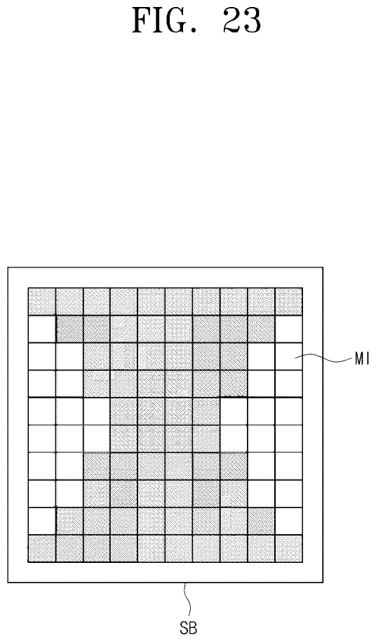

FIG. 23 briefly shows the state of a micromirror when the micromirror changes the shape of a laser through operation position control. Referring to FIG. 23, the case when micromirrors MI maintain an ON state for the entire time for which a specific area is heated is indicated by black and the case when an OFF state is maintained is indicated by white. As shown in FIG. 23, it is possible to adjust the shape or the distribution density of a laser beam in a specific area by controlling micromirrors MI to maintain an ON state or an OFF state for the entire time for which a specific area is heated.

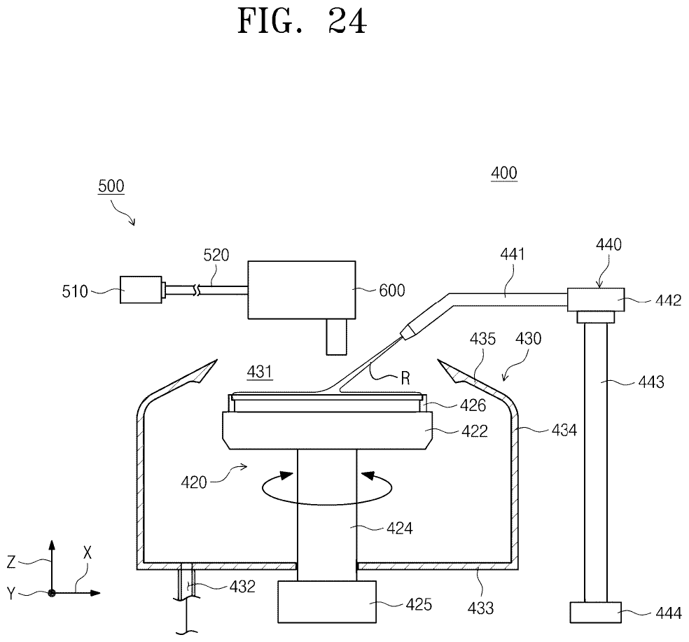

FIG. 24 is a cross-sectional view showing the appearance of a substrate processing apparatus that performs a rinse solution supply step according to an embodiment. The rinse solution supply step S20 supplies a rinse solution R to the substrate M. In more detail, in the rinse solution supply step S20, it is possible to supply a rinse solution R to the substrate M that is rotating. The rinse solution R supplied to the substrate M removes etching impurities produced in the process of performing the etching step S10 from the substrate M. Further, the rinse solution R washes the substrate by replacing the liquid film formed on thee substrate M.

In the embodiment described above, it was described that one laser emission module 600 emits a laser beam L to a specific area SA of a substrate. However, unlike, a plurality of laser emission modules 600 may be provided and the laser emission modules 600 may emit a laser beam L to different regions of the substrate M, respectively. Alternatively, one laser emission module 600 may emit a laser beam to the entire region of a substrate M.

It was described in the embodiment described above that the specific area SA of a substrate M is a rectangle. However, unlike, the specific area SA may be configured in free shapes and sizes on a substrate M and may be the entire region of a substrate M that needs to be heated.

In the example described above, it was exemplarily described that the substrate M that is processed in the liquid processing chamber 400 is a photomask that is a ‘frame’ that is used in an exposure process, but the present invention is not limited thereto. For example, a substrate may be various kinds of substrates that have various shapes and require etching or adjustment of critical dimension of pattern such as a wafer and a glass substrate.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A substrate processing method comprising:
a processing liquid supply step of supplying processing liquid to a substrate; and
a heating step of heating a specific area of the substrate by emitting a laser beam, which is generated from a laser source, to the substrate,
wherein the heating step comprises:
a laser modulation step of modulating the laser beam using a light modulation unit; and
a laser emission step of emitting the laser beam modulated by the light modulation unit to the specific area.

2. The substrate processing method of claim 1, wherein the light modulation unit is a Digital Micro-mirror Device (DMD) unit, and
the DMD unit comprises:
micromirrors provided to be rotatable; and
a board substrate on which the micromirrors are installed.

3. The substrate processing method of claim 2, wherein the laser modulation step selectively switches an ON state in which the laser beam is reflected to the substrate and an OFF state in which the laser beam is dumped by adjusting a direction in which the micromirrors each reflect the laser beam.

4. The substrate processing method of claim 3, wherein, in the laser modulation step, the micromirrors each adjust time for which the laser beam is emitted to the substrate by controlling time for maintaining the ON state and the OFF state.

5. The substrate processing method of claim 3, wherein, in the laser modulation step, the micromirrors each adjust a shape or distribution density of the laser beam in the specific area by maintaining the ON state or the OFF state for entire time for heating the specific area.

6. The substrate processing method of claim 2, wherein, in the laser modulation step, the laser beam is modulated by individually or simultaneously changing a shape or distribution of the laser beam using the DMD unit.

7. The substrate processing method of claim 6, wherein, in the laser modulation step, when the distribution of the laser beam is changed, the laser beam is changed such that intensity of the laser beam to be emitted to an edge region of the specific area is higher than intensity of the laser beam to be emitted to a center region of the specific area.

8. The substrate processing method of claim 6, wherein, in the laser modulation step, when the shape of the laser beam is changed, the laser beam is changed such that side portions of the laser beam are recessed.

9. The substrate processing method of claim 6, wherein, in the laser modulation step, when heat transfer coefficients of the substrate in a first direction in the specific area and in a second direction different from the first direction are different from each other, the laser beam is changed to have different shapes or distribution in the first direction and the second direction to uniformly heat the specific area.

10. The substrate processing method of claim 1, wherein the heating step further comprises a laser type conversion step of converting a type of the laser beam before the laser modulation step, and
a Gaussian-type laser generated from the laser source is converted into a flat top-type laser beam in the laser type conversion step.

11. The substrate processing method of claim 1, wherein the specific area is a rectangle.

12. (canceled)

13. (canceled)

14. (canceled)

15. (canceled)

16. (canceled)

17. A substrate processing method comprising:
a processing liquid supply step of supplying processing liquid to a substrate; and
a heating step of heating a specific area of the substrate by emitting a laser beam, which is generated from a laser source, to the substrate with the processing liquid remaining,
wherein the specific area is a rectangle,
the heating step comprises:
a laser type conversion step of converting a type of the a laser beam into a flat top-type laser beam;
a laser modulation step of modulating the laser beam using a Digital Micro-mirror Device (DMD) unit comprising micromirrors provided to be rotatable; and
a laser emission step of emitting the laser beam modulated by the DMD unit to the specific area, and
the laser modulation step selectively switches an ON state in which the laser beam is reflected to the substrate and an OFF state in which the laser beam is dumped by adjusting a direction in which the micromirrors each reflect the laser beam, and modulates the laser beam by individually or simultaneously changing a shape or distribution of the laser beam.

18. The substrate processing method of claim 17, wherein, in the laser modulation step, when the distribution of the laser beam is changed, the laser beam is changed such that intensity of the laser beam to be emitted to an edge region of the specific area is higher than intensity of the laser beam to be emitted to a center region of the specific area.

19. The substrate processing method of claim 17, wherein, in the laser modulation step, when the shape of the laser beam is changed, the laser beam is changed such that side portions of the laser beam are recessed.

20. The substrate processing method of claim 17, wherein, in the laser modulation step, when heat transfer coefficients of the substrate in a first direction in the specific area and in a second direction different from the first direction are different from each other, the laser beam is changed to have different shapes or distribution in the first direction and the second direction to uniformly heat the specific area.
